(19) United States
(12) Patent Application Publication
(10) Pub. No.: US 2025/0076369 A1
(43) Pub. Date: Mar. 6, 2025

(54) Minimum Integrated Circuit Operating Voltage Searching Method and Minimum Integrated Circuit Operating Voltage Searching System Capable of Blending Two Prediction Models

(71) Applicant: MEDIATEK INC., Hsin-Chu (TW)

(72) Inventors: Ronald Kuo-Hua Ho, Hsinchu City (TW); Kun-Yu Wang, Hsinchu City (TW); Yen-Chang Shih, Hsinchu City (TW); Sung-Te Chen, Hsinchu City (TW); Cheng-Han Wu, Hsinchu City (TW); Yi-Ying Liao, Hsinchu City (TW); Chun-Ming Huang, Hsinchu City (TW); Yen-Feng Lu, Hsinchu City (TW); Ching-Yu Tsai, Hsinchu City (TW); Tai-Lai Tung, Hsinchu City (TW); Kuan-Fu Lin, Hsinchu City (TW); Bo-Kang Lai, Hsinchu City (TW); Yao-Syuan Lee, Hsinchu City (TW); Tsyr-Rou Lin, Hsinchu City (TW); Ming-Chao Tsai, Hsinchu City (TW); Li-Hsuan Chiu, Hsinchu City (TW)

(73) Assignee: MEDIATEK INC., Hsin-Chu (TW)

(21) Appl. No.: 18/637,448

(22) Filed: Apr. 16, 2024

Related U.S. Application Data
(60) Provisional application No. 63/580,403, filed on Sep. 4, 2023.

(51) Int. Cl. G01R 31/28; G06N 3/08; H03K 3/01

(52) U.S. Cl. CPC G01R 31/2884; G06N 3/08; H03K 3/01

(57) ABSTRACT

A minimum IC operating voltage searching method includes acquiring a corner type of an IC, acquiring ring oscillator data of the IC, generating a first prediction voltage according to the corner type and the ring oscillator data by using a training model, generating a second prediction voltage according to the ring oscillator data by using a non-linear regression approach under an N-ordered polynomial, and generating a predicted minimum IC operating voltage according to the first prediction voltage and the second prediction voltage. N is a positive integer.

### CROSS REFERENCE TO RELATED APPLICATIONS

This application claims the benefit of U.S. Provisional Application No. 63/580,403, filed on Sep. 4, 2023. The content of the application is incorporated herein by reference.

### BACKGROUND

Traditionally, the performance range provided to designers is only applicable to digital circuits in the form of “process corners”. The process corners are indicated as speed variations of an N-type metal oxide semiconductor field effect transistor (NMOS) and a P-type metal oxide semiconductor field effect transistor (PMOS) within a rectangular range determined by four corners. Further, when device models corresponding to each corner are extracted from a chip, testing structures on-chip for the NMOS and the PMOS exhibit different gate delays. Thus, when chips are able to satisfy the performance metrics of these corners, they can be considered as qualified chips. Since speed variations are correlated to the process corners of the chips, minimum integrated circuit (IC) operating voltages for driving the chips are different.

Since the minimum IC operating voltages for driving the chips are different, searching a real minimum IC operating voltage for each chip is required for improving an IC operation performance and reducing power consumption. However, currently, no efficient method for searching the real minimum IC operating voltages to configure infinity voltage bins of the ICs.

Therefore, developing a minimum IC operating voltage searching system capable of rapidly and efficiently searching the real minimum IC operating voltage for each chip is an important design issue.

### SUMMARY

In an embodiment of the present invention, a minimum integrated circuit (IC) operating voltage searching method is disclosed. The minimum IC operating voltage searching method comprises acquiring a corner type of an IC, acquiring ring oscillator data of the IC, generating a first prediction voltage according to the corner type and the ring oscillator data by using a training model, generating a second prediction voltage according to the ring oscillator data by using a non-linear regression approach under an N-ordered polynomial, and generating a predicted minimum IC operating voltage according to the first prediction voltage and the second prediction voltage. N is a positive integer.

In another embodiment of the present invention, a minimum IC operating voltage searching system is disclosed. The minimum IC operating voltage searching system comprises an input module, a memory, a testing module, a processor, and an output module. The input module is configured to receive input data. The testing module is configured to test an IC by using a plurality of minimum IC operating voltages. The processor is coupled to the input module, the memory, and the testing module. The output module is coupled to the testing module and configured to output a real minimum IC operating voltage. The processor acquires a corner type and ring oscillator data of the IC through the input module. The processor generates a first prediction voltage according to the corner type and the ring oscillator data by using a training model saved in the memory. The processor generates a second prediction voltage according to the ring oscillator data by using a non-linear regression approach under an N-ordered polynomial. The processor generates a predicted minimum IC operating voltage according to the first prediction voltage and the second prediction voltage. N is a positive integer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a minimum integrated circuit (IC) operating voltage searching system according to an embodiment of the present invention.

FIG. 2 is an illustration of signal flows for blending a first prediction voltage and a second prediction voltage of the minimum IC operating voltage searching system in FIG. 1.

FIG. 3 is a flow chart of performing a minimum IC operating voltage searching method by the minimum IC operating voltage searching system in FIG. 1.

### DETAILED DESCRIPTION

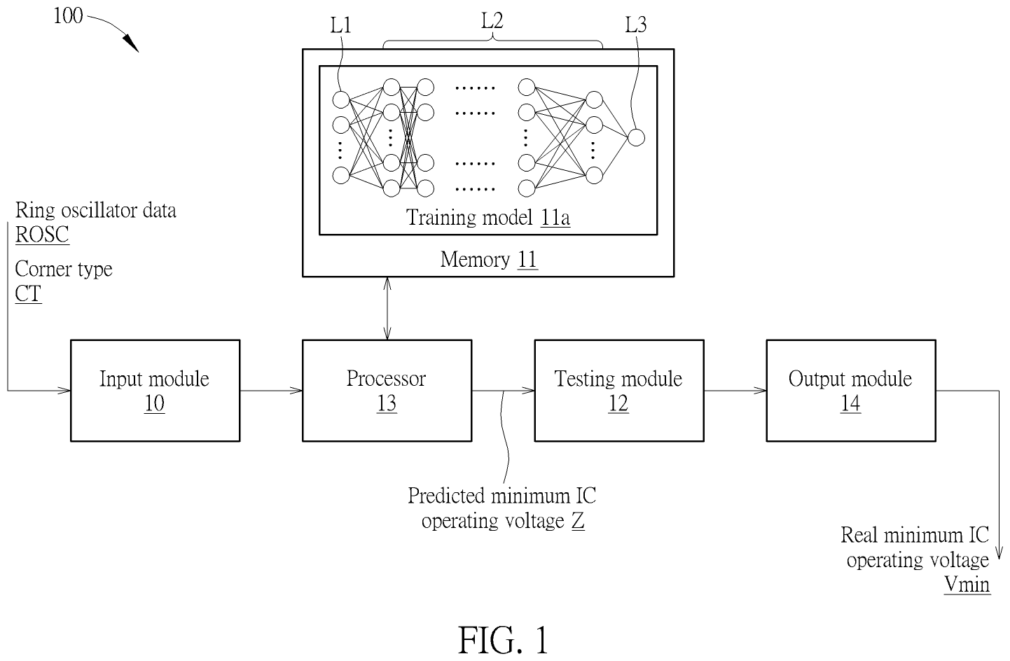

FIG. 1 is a block diagram of a minimum integrated circuit (IC) operating voltage searching system 100 according to an embodiment of the present invention. The minimum IC operating voltage searching system 100 includes an input module 10, a memory 11, a testing module 12, a processor 13, and an output module 14. The input module 10 can be any data input interface or data port. The output module 14 can be any digital data output interface. Here, the input module 10 is used for receiving input data. The testing module 12 is used for testing an IC (or say, driving the IC) by using a plurality of minimum IC operating voltages. The processor 13 is coupled to the input module 10, the memory 11, and the testing module 12. The output module 14 is coupled to the testing module 12 for outputting a real minimum IC operating voltage Vmin. In the minimum IC operating voltage searching system 100, the input data can include a corner type CT and ring oscillator data ROSC of the IC. The corner type CT of the IC is determined by speed variations of an N-type metal oxide semiconductor field effect transistor (NMOS) and a P-type metal oxide semiconductor field effect transistor (PMOS) within a rectangular range of process corners. The ring oscillator data ROSC is determined by the speed of a ring oscillator for testing physical features. The ring oscillator data ROSC can be used for monitoring the drift of a manufacturing process and checking if the circuit performance is changed during the manufacturing process. The memory 11 includes a training model 11a. The processor 13 can establish the training model 11a by using a neural network regression (NNR) architecture. However, the training model 11a can be trained by any neural network (NN). For example, the training model 11a can include an input layer L1, at least one hidden layer L2, and an output layer L3. The processor 13 can input the corner type CT and the ring oscillator data ROSC to the input layer L1 of the training model 11a for generating the first prediction voltage outputted from the output layer L3 of the training model 11a after the training model 11a is established. In the minimum IC operating voltage searching system 100, the processor 13 can acquire the corner type CT and the ring oscillator data ROSC of the IC through the input module 10. Then, the processor 13 can generate a first prediction voltage according to the corner type CT and the ring oscillator data ROSC by using the training model 11a saved in the memory 11. Then, the processor 13 can generate a second prediction voltage according to the ring oscillator data ROSC by using a non-linear regression (NLR) approach under an N-ordered polynomial. The processor 13 can generate a predicted minimum IC operating voltage Z operating voltage according to the first prediction voltage and the second prediction voltage. N is a positive integer. Finally, the testing module 12 can find and output the real minimum IC operating voltage Vmin to the output module 14 according to the predicted minimum IC operating voltage Z. Details of searching the real minimum IC operating voltage Vmin are illustrated below.

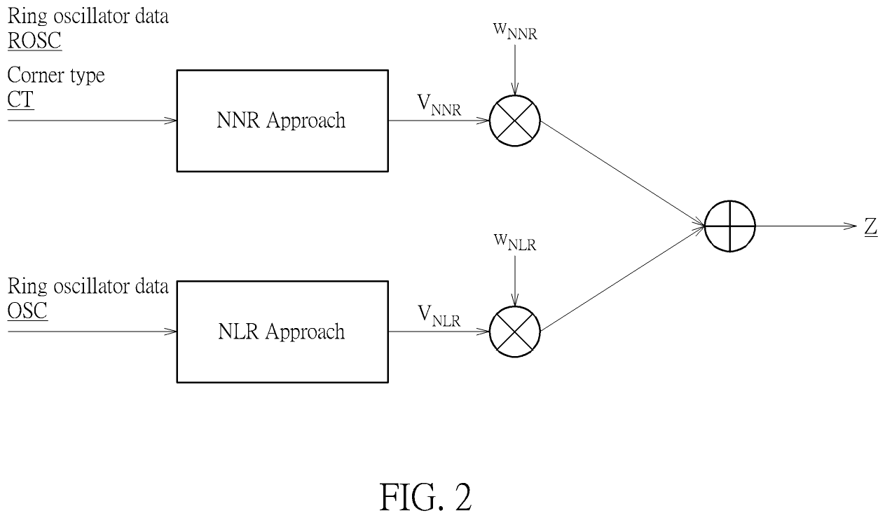

FIG. 2 is an illustration of signal flows for blending a first prediction voltage V_{NNR} and a second prediction voltage V_{NLR} of the minimum IC operating voltage searching system 100. In the minimum IC operating voltage searching system 100, the predicted minimum IC operating voltage Z can be generated by using a neural network regression (NNR) approach and a non-linear regression (NLR) approach. In other words, an adaptive voltage scaling technology under infinity voltage bins can be implemented for generating the predicted minimum IC operating voltage Z by using the NNR approach and the NLR approach. Details are illustrated later.

In the NNR approach, as previously mentioned, the training model 11a can include the input layer L1, at least one hidden layer L2, and the output layer L3. The ring oscillator data ROSC can include M data fields, such as OSC₁, OSC₂, and OSC₃ to OSC_{M}. M is a positive integer. The M data fields OSC₁, OSC₂, and OSC₃ to OSC_{M} of the ring oscillator data ROSC and the corner type CT can be inputted to (M+1) neurons of the input layer L1. Here, the ring oscillator data ROSC and the corner type CT are digital data. At least one hidden layer L2 can be regarded as a function for processing the ring oscillator data ROSC and the corner type CT. Finally, the output layer L3 can output the first prediction voltage V_{NNR}. In other words, the first prediction voltage V_{NNR} can be expressed as a function output, as illustrated below.

$${V}_{N N R} = f ( \begin{matrix}{OSC}_{1} , & {OSC}_{2} , & … & {OSC}_{M} , & CT )\end{matrix}$$

Here, f(●) is a function of the training model 11a. By using the NNR approach, the processor 13 can acquire the first prediction voltage V_{NNR} of the IC.

In the NLR approach, the processor 13 can acquire a regression weighting bias and N regression weighting vectors under an NLR optimization function according to N ring oscillator vectors. Here, the NLR optimization function can be expressed as below.

$${min}_{w} \vert \vert {w}_{0} + {\sum }_{k = 1}^{N} {w}_{k}^{T} {x}^{k} - y \vert \vert + α \cdot ‖ w ‖$$

Here, w₀ is the regression weighting bias. wₖ^{T} is a transpose of k-th regression weighting vector. x^{k} is k-th ring oscillator vector. α is a predetermined constant. ∥w∥ is an inner product sum of the regression weighting bias w₀ and the N regression weighting vectors w₁ to w_{N}. N ring oscillator vectors x¹ to x^{N} and the parameter y are observed data. In the NLR approach, the ring oscillator data ROSC can be formed by the N ring oscillator vectors x¹ to x^{N}. ∥w∥ can be regarded as a regularization term for preventing over-fitting to the observed data (x, y), especially in large N. N ring oscillator vectors x¹ to x^{N} and the N regression weighting vectors w₁ to w_{N} can form the N-ordered polynomial, denoted as

$${\sum }_{k = 1}^{N} {w}_{k}^{T} {x}^{k} .$$

Specifically, the NLR optimization function corresponds to a convex optimization problem. The convex optimization problem can be solved by deriving the regression weighting bias w₀ and the N regression weighting vectors w₁ to w_{N}. After the regression weighting bias w₀ and the N regression weighting vectors w₁ to w_{N} are derived, the processor 13 can generate the second prediction voltage V_{NLR} as

$${w}_{0} + {\sum }_{k = 1}^{N} {w}_{k}^{T} {x}^{k} .$$

In other words, by using the NLR approach, the processor 13 can generate the second prediction voltage V_{NLR} according to the regression weighting bias w₀, the N regression weighting vectors w₁ to w_{N}, and the N ring oscillator vectors x¹ to x^{N}.

As previously mentioned, the NNR approach can be used for generating the first prediction voltage V_{NNR} of the IC. The NLR approach can be used for generating the second prediction voltage V_{NLR} Of the IC. Particularly, properties of the NLR approach and the NNR approach can be listed in Table T1.

TABLE T1

| | Data Requirement | Generalization | Model |
|---|---|---|---|
| Method | Amount | Capability | Complexity |
| NNR approach | High | High | High |
| NLR approach | Low | Low | Low |

In the minimum IC operating voltage searching system 100, to improve flexibility of generating the predicted minimum IC operating voltage Z, a blending technology of the NNR approach and the NLR approach is introduced. In the embodiment, in FIG. 2, the processor 13 can generate the predicted minimum IC operating voltage Z by linearly combining the first prediction voltage V_{NNR} and the second prediction voltage V_{NLR} according to the first weighting value W_{NNR} and the second weighting value W_{NLR}. Derivation details are illustrated below.

First, the predicted minimum IC operating voltage Z can be expressed as:

$$Z = {V}_{N N R} \times {W}_{N N R} + {V}_{N L R} \times {W}_{N L R}$$

The predicted minimum IC operating voltage Z can be optimized by minimizing its variance, expressed as:

$$min \{ E [ {( Z - \overline{Z} )}^{2} ] \}$$

Here, Z̅ is a mean value of Z. E[(Z−Z̅)²] is a variance of Z. A sum of the first weighting value W_{NNR} and the second weighting value W_{NLR} is normalized to one, regarded as a weighting constraint. Therefore, optimizing the predicted minimum IC operating voltage Z can be regarded as a constrained optimization problem. The constrained optimization problem can be solved by using a Lagrange multiplier λ. The optimization function can be expressed as:

$$L ( {W}_{NNR} , {W}_{N L R} ) = E [ {( Z - \overline{Z} )}^{2} ] - λ \times ( {W}_{N N R} + {W}_{N L R} - 1 )$$

The solutions of the optimization function can be derived below.

$$L ( {W}_{NNR} , {W}_{N L R} ) = E [ {( Z - \overline{Z} )}^{2} ] - λ \times ( {W}_{N N R} + {W}_{N L R} - 1 ) = E [ {W}_{NNR}^{2} \times {( {V}_{NNR} - \overline{{V}_{NNR}} )}^{2} + {W}_{NLR}^{2} \times {( {V}_{NLR} - \overline{{V}_{NLR}} )}^{2} + 0 ] - λ \times ( {W}_{N N R} + {W}_{N L R} - 1 )$$

$$L ( {W}_{NNR} , {W}_{N L R} ) = {W}_{NNR}^{2} \times {σ}_{NNR}^{2} + {W}_{NLR}^{2} \times {σ}_{NLR}^{2} - λ \times ( {W}_{N N R} + {W}_{N L R} - 1 )$$

Using a partial derivative technology, the optimization function can be derived as:

$$\frac{\partial L ( {W}_{NNR} , {W}_{N L R} )}{\partial {W}_{N N R}} = 2 \times {W}_{N N R} \times {σ}_{N N R}^{2} - λ = 0$$

Therefore, the first weighting value W_{NNR} can be expressed as:

$${W}_{N N R} = \frac{λ}{2 \times {σ}_{N N R}^{2}}$$

Using the partial derivative technology, the optimization function can be derived as:

$$\frac{\partial L ( {W}_{NNR} , {W}_{N L R} )}{\partial {W}_{N L R}} = 2 \times {W}_{N L R} \times {σ}_{N L R}^{2} - λ = 0$$

Therefore, the second weighting value W_{NLR} can be expressed as:

$${W}_{N L R} = \frac{λ}{2 \times {σ}_{N L R}^{2}}$$

Since the sum of the first weighting value W_{NNR} and the second weighting value W_{NLR} is normalized to one (i.e., W_{NNR}+W_{NLR}=1), the Lagrange multiplier λ can be derived as:

$$λ = \frac{2 \times {σ}_{N N R}^{2} \times {σ}_{N L R}^{2}}{{σ}_{N N R}^{2} + {σ}_{N L R}^{2}}$$

Substituting λ into the first weighting value W_{NNR} can derive a closed-form of the first weighting value W_{NNR}.

$${W}_{N N R} = \frac{{σ}_{N L R}^{2}}{{σ}_{N N R}^{2} + {σ}_{N L R}^{2}}$$

Substituting A into the second weighting value W_{NLR} can derive a closed-form of the second weighting value W_{NLR}.

$${W}_{N L R} = \frac{{σ}_{N N R}^{2}}{{σ}_{N N R}^{2} + {σ}_{N L R}^{2}}$$

Here, σ²_{NNR} is a variance of the first weighting value W_{NNR}. σ²_{NLR} is a variance of the second weighting value W_{NLR}. In other words, the processor 13 can acquire the first weighting value W_{NNR} corresponding to the first prediction voltage V_{NNR} according to the variance σ²_{NNR} of the first prediction voltage V_{NNR} and the variance σ²_{NLR} of the second prediction voltage V_{NLR}. The processor 13 can acquire the second weighting value W_{NLR} corresponding to the second prediction voltage V_{NLR} according to the variance σ²_{NNR} of the first prediction voltage V_{NNR} and the variance σ²_{NLR} of the second prediction voltage V_{NLR}. In the embodiment, when the variance σ²_{NNR} of the first prediction voltage V_{NNR} increases, the second weighting value W_{NLR} increases. When the variance σ²_{NLR} of the second prediction voltage V_{NLR} increases, the first weighting value W_{NNR} increases. Briefly, the processor 13 uses the Lagrange multiplier λ for deriving the first weighting value W_{NNR} and the second weighting value W_{NLR}. As a result, the processor 13 can use the first weighting value W_{NNR} and the second weighting value W_{NLR} for blending the first prediction voltage V_{NNR} and the second prediction voltage V_{NLR}. Finally, the predicted minimum IC operating voltage Z can be expressed as:

$$Z = {V}_{N N R} \times \frac{{σ}_{N L R}^{2}}{{σ}_{N N R}^{2} + {σ}_{N L R}^{2}} + {V}_{N L R} \times \frac{{σ}_{N N R}^{2}}{{σ}_{N N R}^{2} + {σ}_{N L R}^{2}}$$

After the predicted minimum IC operating voltage Z is acquired, the processor 13 can set an initial minimum IC operating voltage to the predicted minimum IC operating voltage Z. For example, the initial minimum IC operating voltage can be set to 0.8V. Then, the testing module 12 can test the IC by using the plurality of minimum IC operating voltages generated according to the initial minimum IC operating voltage for searching the real minimum IC operating voltage Vmin. For example, when the initial minimum IC operating voltage is set to 0.8V, the plurality of minimum IC operating voltages can be smaller than 0.8V. The testing module 12 can use the plurality of minimum IC operating voltages for driving the IC. Then, the testing module 12 can search the real minimum IC operating voltage Vmin from the plurality of minimum IC operating voltages. However, any hardware or technology modification falls into the scope of the present invention. For example, the processor sets a searching bias voltage Δ. The processor 13 can set an initial minimum IC operating voltage to a sum of the predicted minimum IC operating voltage and the searching bias voltage Δ. For example, the initial minimum IC operating voltage can be set to 0.8V+Δ. The searching bias voltage Δ can be used for adjusting a convergence rate of searching the real minimum IC operating voltage Vmin.

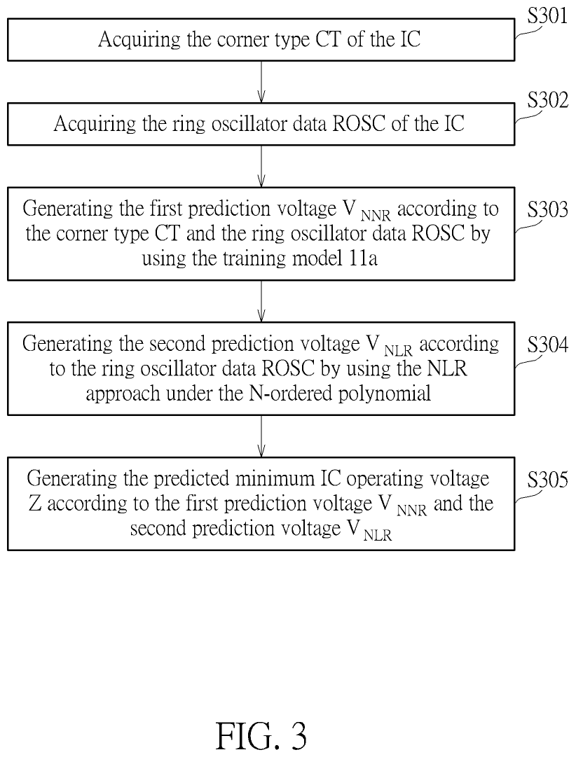

FIG. 3 is a flow chart of performing a minimum IC operating voltage searching method by the minimum IC operating voltage searching system 100. The minimum IC operating voltage searching method includes step S301 to step S305. Step S301 to step S305 are illustrated below.
step S301: acquiring the corner type CT of the IC;
step S302: acquiring the ring oscillator data ROSC of the IC;
step S303: generating the first prediction voltage V_{NNR} according to the corner type CT and the ring oscillator data ROSC by using the training model 11a;
step S304: generating the second prediction voltage V_{NLR} according to the ring oscillator data ROSC by using the NLR approach under the N-ordered polynomial;
step S305: generating the predicted minimum IC operating voltage Z according to the first prediction voltage V_{NNR} and the second prediction voltage V_{NLR}.

Details of step S301 to step S305 are previously illustrated. Thus, they are omitted here. In the minimum IC operating voltage searching system 100, an artificial intelligence (AI) based training model (say, the NNR approach) and the NLR approach are used for generating the predicted minimum IC operating voltage Z. The predicted minimum IC operating voltage Z can be set to the initial minimum IC operating voltage for searching the real minimum IC operating voltage Vmin. Since the initial minimum IC operating voltage is dynamically changed for different ICs, the convergence rate (or say, the processing speed) of searching the real minimum IC operating voltage Vmin can be greatly improved.

To sum up, the present invention discloses a minimum IC operating voltage searching method and a minimum IC operating voltage searching system. The minimum IC operating voltage searching system can use the NNR approach and the NLR approach for generating the predicted minimum IC operating voltage. The weighting values for blending the NNR approach and the NLR approach can be dynamically adjusted according to variances of the prediction voltages of the NNR approach and the NLR approach. The predicted minimum IC operating voltage can be set to the initial minimum IC operating voltage for searching the real minimum IC operating voltage. Thus, the initial minimum IC operating voltage can be dynamically changed for different ICs. As a result, the minimum IC operating voltage searching system can be applied to the adaptive voltage scaling technology under infinity voltage bins and can provide high efficiency for searching the real minimum IC operating voltage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A minimum integrated circuit (IC) operating voltage searching method comprising:
acquiring a corner type of an IC;
acquiring ring oscillator data of the IC;
generating a first prediction voltage according to the corner type and the ring oscillator data by using a training model;
generating a second prediction voltage according to the ring oscillator data by using a non-linear regression (NLR) approach under an N-ordered polynomial; and
generating a predicted minimum IC operating voltage according to the first prediction voltage and the second prediction voltage;
wherein N is a positive integer.

2. The method of claim 1, further comprising:
establishing the training model by using a neural network regression (NNR) architecture; and
inputting the corner type and the ring oscillator data to an input layer of the training model for generating the first prediction voltage outputted from an output layer of the training model after the training model is established.

3. The method of claim 1, wherein generating the second prediction voltage according to the ring oscillator data by using the NLR approach under the N-ordered polynomial comprises:
acquiring a regression weighting bias and N regression weighting vectors under an NLR optimization function according to N ring oscillator vectors; and
generating the second prediction voltage according to the regression weighting bias, the N regression weighting vectors, and the N ring oscillator vectors;
wherein the ring oscillator data is formed by the N ring oscillator vectors, and the N ring oscillator vectors and the N regression weighting vectors form the N-ordered polynomial.

4. The method of claim 3, wherein the NLR optimization function is expressed as:
$${min}_{w} \vert \vert {w}_{0} + {\sum }_{k = 1}^{N} {w}_{k}^{T} {x}^{k} - y \vert \vert + α \cdot ‖ w ‖$$
w₀ is the regression weighting bias, wₖ^{T} is a transpose of k-th regression weighting vector, x^{k} is k-th ring oscillator vector, α is a pre-determined constant, and ∥w∥ is an inner product sum of the regression weighting bias and the N regression weighting vectors.

5. The method of claim 1, wherein generating the predicted minimum IC operating voltage according to the first prediction voltage and the second prediction voltage comprises:
acquiring a first weighting value corresponding to the first prediction voltage according to a first variance of the first prediction voltage and a second variance of the second prediction voltage;
acquiring a second weighting value corresponding to the second prediction voltage according to the first variance of the first prediction voltage and the second variance of the second prediction voltage; and
generating the predicted minimum IC operating voltage by linearly combining the first prediction voltage and the second prediction voltage according to the first weighting value and the second weighting value.

6. The method of claim 5, wherein when the first variance of the first prediction voltage increases, the second weighting value increases, and when the second variance of the second prediction voltage increases, the first weighting value increases.

7. The method of claim 5, wherein a sum of the first weighting value and the second weighting value is normalized to one.

8. The method of claim 5, further comprising:
using a Lagrange multiplier for deriving the first weighting value and the second weighting value; and
using the first weighting value and the second weighting value for blending the first prediction voltage and the second prediction voltage.

9. The method of claim 1, further comprising:
setting an initial minimum IC operating voltage to the predicted minimum IC operating voltage; and
testing the IC by using a plurality of minimum IC operating voltages generated according to the initial minimum IC operating voltage for searching a real minimum IC operating voltage;
wherein the initial minimum IC operating voltage is dynamically changed for different ICs.

10. The method of claim 1, further comprising:
setting a searching bias voltage;
setting an initial minimum IC operating voltage to a sum of the predicted minimum IC operating voltage and the searching bias voltage; and
testing the IC by using a plurality of minimum IC operating voltages generated according to the initial minimum IC operating voltage for searching a real minimum IC operating voltage;
wherein the initial minimum IC operating voltage is dynamically changed for different ICs.

11. A minimum integrated circuit (IC) operating voltage searching system comprising:
an input module configured to receive input data;
a memory;
a testing module configured to test an IC by using a plurality of minimum IC operating voltages;
a processor coupled to the input module, the memory, and the testing module; and
an output module coupled to the testing module and configured to output a real minimum IC operating voltage;
wherein the processor acquires a corner type and ring oscillator data of the IC through the input module, the processor generates a first prediction voltage according to the corner type and the ring oscillator data by using a training model saved in the memory, the processor generates a second prediction voltage according to the ring oscillator data by using a non-linear regression (NLR) approach under an N-ordered polynomial, the processor generates a predicted minimum IC operating voltage according to the first prediction voltage and the second prediction voltage, and N is a positive integer.

12. The system of claim 11, wherein the processor establishes the training model by using a neural network regression (NNR) architecture, and the processor inputs the corner type and the ring oscillator data to an input layer of the training model for generating the first prediction voltage outputted from an output layer of the training model after the training model is established.

13. The system of claim 11, wherein the processor acquires a regression weighting bias and N regression weighting vectors under an NLR optimization function according to N ring oscillator vectors, the processor generates the second prediction voltage according to the regression weighting bias, the N regression weighting vectors, and the N ring oscillator vectors, the ring oscillator data is formed by the N ring oscillator vectors, and the N ring oscillator vectors and the N regression weighting vectors form the N-ordered polynomial.

14. The system of claim 13, wherein the NLR optimization function is expressed as:
$${min}_{w} \vert \vert {w}_{0} + {\sum }_{k = 1}^{N} {w}_{k}^{T} {x}^{k} - y \vert \vert + α \cdot ‖ w ‖$$
w₀ is the regression weighting bias, wₖ^{T} is a transpose of k-th regression weighting vector, x^{k} is k-th ring oscillator vector, α is a pre-determined constant, and ∥w∥ is an inner product sum of the regression weighting bias and the N regression weighting vectors.

15. The system of claim 11, wherein the processor acquires a first weighting value corresponding to the first prediction voltage according to a first variance of the first prediction voltage and a second variance of the second prediction voltage, the processor acquires a second weighting value corresponding to the second prediction voltage according to the first variance of the first prediction voltage and the second variance of the second prediction voltage, and the processor generates the predicted minimum IC operating voltage by linearly combining the first prediction voltage and the second prediction voltage according to the first weighting value and the second weighting value.

16. The system of claim 15, wherein when the first variance of the first prediction voltage increases, the second weighting value increases, and when the second variance of the second prediction voltage increases, the first weighting value increases.

17. The system of claim 15, wherein a sum of the first weighting value and the second weighting value is normalized to one.

18. The system of claim 15, where the processor uses a Lagrange multiplier for deriving the first weighting value and the second weighting value, and the processor uses the first weighting value and the second weighting value for blending the first prediction voltage and the second prediction voltage.

19. The system of claim 11, wherein the processor sets an initial minimum IC operating voltage to the predicted minimum IC operating voltage, the testing module tests the IC by using the plurality of minimum IC operating voltages generated according to the initial minimum IC operating voltage for searching the real minimum IC operating voltage, and the initial minimum IC operating voltage is dynamically changed for different ICs.

20. The system of claim 11, wherein the processor sets a searching bias voltage, the processor sets an initial minimum IC operating voltage to a sum of the predicted minimum IC operating voltage and the searching bias voltage, the testing module tests the IC by using the plurality of minimum IC operating voltages generated according to the initial minimum IC operating voltage for searching the real minimum IC operating voltage, and the initial minimum IC operating voltage is dynamically changed for different ICs.
